(19) United States
(12) Patent Application Publication
(10) Pub. No.: US 2005/0230842 A1
(43) Pub. Date: Oct. 20, 2005

(54) Multi-chip flip package with substrate for inter-die coupling

(75) Inventors: Leland S. Swanson, McKinney, TX (US); William D. Boyd, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/827,836

(22) Filed: Apr. 20, 2004

(51) Int. Cl. H01L 23/48

(52) U.S. Cl. 257/778

(57) ABSTRACT

A method comprising coupling a substrate interconnect to a substrate pad, attaching at least two flip chips to said substrate interconnect to electrically connect together said chips, and coupling at least one lead to each of the chips.

### BACKGROUND

Advances in integrated circuit (“IC”) packaging techniques allow designers to fabricate IC packages that continue to decrease in size and increase in power density. For such endeavors, fabricating packages comprising more than one die may often prove advantageous, especially if each performs a different function that may be exploited in a particular application.

Electrically coupling multiple dies in an IC package can be accomplished using wirebonds, wherein one or more wires are bonded to two dies, thereby electrically coupling the dies. However, the use of wirebonds may present substantial manufacturing costs. Additionally, to ensure proper functionality, at least some wirebonds may be required to have at least a certain minimum length. This minimum length requirement is problematic to designers trying to decrease IC package size while increasing power density. Furthermore, each wirebond carries some degree of undesirable inductance that may be detrimental to IC performance, particularly in high-speed applications. Alternatives to such wirebonding techniques include soldering flip chips to a lead frame of a package. However, various such alternatives may limit the number of interconnects that may be implemented within a package of a particular size.

### BRIEF SUMMARY

The problems noted above are solved in large part by a method for coupling a substrate interconnect to a substrate pad, attaching at least two dies to said substrate interconnect to electrically connect together said dies, and coupling at least one lead to each of the dies.

### BRIEF DESCRIPTION OF THE DRAWINGS

For a detailed description of exemplary embodiments of the invention, reference will now be made to the accompanying drawings in which:

FIG. 1 illustrates an IC package in which multiple dies are interconnected in accordance with a preferred embodiment of the invention;

FIG. 2 illustrates a process for fabricating the package of FIG. 1;

FIG. 3 illustrates an alternative embodiment of the IC package in which the orientation of the leads is reversed; and

FIG. 4 illustrates yet another alternative embodiment in which a recessed area is formed in a substrate pad.

### NOTATION AND NOMENCLATURE

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to. . . . ” Also, the term “couple” or “couples” is intended to mean either an indirect or direct electrical connection. Thus, if a first device couples to a second device, that connection may be through a direct electrical connection, or through an indirect electrical connection by way of other devices and connections. Additionally, the terms “die” and “chip” or “dies,” “dice” and “chips” may be used interchangeably.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

In accordance with a preferred embodiment, a technique is presented herein in which a substrate is used to interconnect multiple dies in an IC package. IC packages comprising multiple dies may generate a considerable amount of heat. Accordingly, some embodiments of the invention may comprise thermally coupling a heat “slug” to one or more of the dies to enhance heat dissipation.

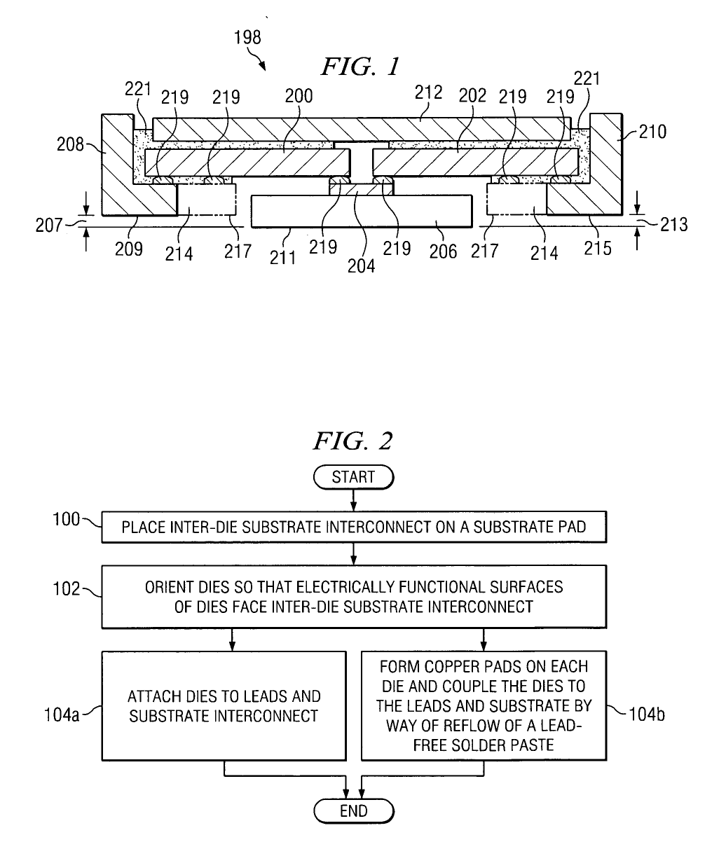

FIG. 1 illustrates a portion of an IC package 198 comprising an inter-die substrate interconnect 204 bonded to a substrate pad 206 and electrically connecting together two dies 200, 202 (e.g., processors, memory chips) by way of pads 219 (e.g., copper pads, solder bumps, or any suitable material). The inter-die substrate interconnect 204 may be any suitable, electrically conductive material (e.g., ultra thin silicon, a ceramic material, an organic material). Although the embodiment of FIG. 1 comprises two dies, any number of dies may be used. Electrical pathways may be formed in or on the substrate interconnect 204 to electrically connect two or more pads 219 together. As such, one or more electrical connections can be made between the dies 200, 202 by way of the substrate interconnect 204. In some embodiments, the dies 200, 202 may be thermally bonded to a heat slug 212. The heat slug 212 functions to dissipate heat from the dies 200, 202. The heat slug 212 may be fabricated from aluminum, a zinc alloy or any other suitable material.

In at least some embodiments, the inter-die substrate interconnect 204 may comprise one or more active circuits (not shown) that can serve any purpose (i.e., as defined by an IC designer) in the package 198. For example, such an active circuit may comprise a digital input/output circuit. The circuit may also comprise radio frequency passive circuit elements such as inductors, filters, caps, etc. The active circuit also may be used to help isolate a low voltage analog circuit from a high voltage analog circuit. Any accelerometer, magnetic field, or other sensor may be placed on one of the dies 200, 202, and/or the substrate interconnect 204.

Each of the dies 200, 202 also may be coupled to at least one lead 208, 210 and, if desired, additional leads 214, all by way of pads 219. In some embodiments, at least one of a plurality of dies may be independent of any direct connections to any of the leads 208, 210, 214. The IC package 198 of FIG. 1 is constructed using a process as shown in FIG. 2. The process may begin at 100 with the attachment of the inter-die substrate interconnect 204 to a substrate pad 206 as shown in FIG. 1. Both dies 200, 202 then are flipped so that an electrically functional surface of each of the dies 200, 202 faces the inter-die substrate interconnect 204 (block 102). In some embodiments, the inter-die substrate interconnect 204 is bonded to the dies 200, 202 by way of pads 219 to establish inter-die coupling between the dies 200, 202. The dies 200, 202 also are attached to the leads 208, 210, respectively, by way of the pads 219 (block 104a). In this embodiment, the pads 219 may comprise solder bumps (i.e., solder balls). In alternative embodiments, the pads 219 may comprise copper pads that are formed on the dies 200, 202. The dies 200, 202 then are coupled to the leads 208, 210 and the inter-die substrate interconnect 204 by way of reflow of a solder paste, such as a lead-free solder paste (block 104b). In still other embodiments, plated solder may be used instead of solder bumps and copper pads. In still yet other embodiments, any combination of plated solder, solder bumps, copper pads or any other appropriate adhesive substance may be used. In at least some embodiments, wirebonds also may be used to couple two or more dies. While FIG. 1 shows only one lead 208, 210 connected to each of the dies 200, 202, any number of additional leads 214 connections may be established. Such additional connections may be useful to dissipate heat from high thermal dissipation areas of the dies 200, 202.

The IC package 198 may comprise package epoxy 221. The heat slug 212 may be encompassed within the package epoxy 221 or exposed through the package epoxy 221. Because the leads 208, 210, 214 are formed pointing upward (i.e., away from the substrate pad 206 and toward the heat slug 212), the configuration of FIG. 1 is useful in applications wherein the heat slug 210 is exposed from the package epoxy 221. In such applications, the heat slug 212 and the leads 208, 210, 214 may be soldered to a printed circuit (“PC”) board (not shown) or any other suitable object, depending upon a designer's goals.

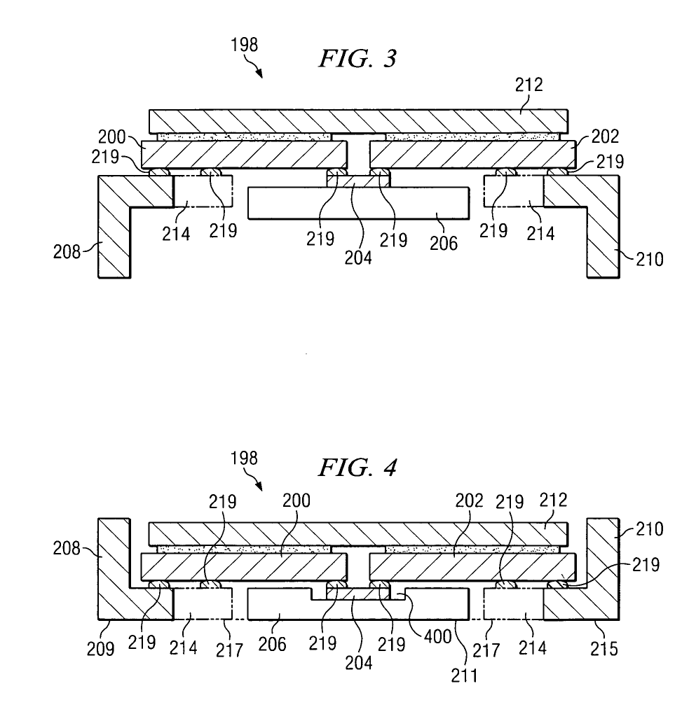

In applications requiring heat slugs external to a package (e.g., high power dissipation applications) or heat slugs that radiantly dissipate heat in the package, the leads 208, 210, 214 may be formed pointing downward (i.e., away from the heat slug 212 and toward the substrate pad 206), as shown in FIG. 3. The embodiment presented in FIG. 3 is generally identical to the embodiment presented in FIG. 1, with the exception of the direction of the leads 208, 210, 214.

Referring again to FIG. 1, the lead 208 comprises a bottom surface 209 of the lead 208 that may not be aligned with the bottom surface 211 of the substrate pad 206, thus creating a gap 207. Similarly, a bottom surface 215 of the lead 210 may not be aligned with the bottom surface 211 of the substrate pad 206, thereby creating a gap 213. In some applications, making the surfaces 209, 211, 215 coplanar may be preferred. Accordingly, FIG. 4 illustrates yet another exemplary embodiment that is generally identical to the embodiments illustrated in FIGS. 1 and 3, with the exception of a recessed area 400 formed in the substrate pad 206. The recessed area 400 contains some or all of the inter-die substrate interconnect 204. The recessed area 400 enables the bottom surface 209 of the lead 208, the bottom surface 215 of the lead 210, bottom surfaces 217 of the additional leads 214, and a bottom surface 211 of the substrate pad 206 all to generally be coplanar with each other. Thus, by accommodating some or all of the inter-die substrate interconnect 204, the recessed area 400 enables the leads 208, 210, 214 and the substrate pad 206 to evenly rest on any flat surface. This embodiment may be useful in applications that require all leads 208, 210, 214 and the substrate pad 206 to rest on a single, flat sheet of metal. The recessed area 400 may be of any suitable size. In at least some embodiments, the recessed area 400 is sized to accommodate some or all of the inter-die substrate interconnect 204. Further, the recessed area 400 may be formed using any appropriate technique, such as wet-etching or hammer punching. In the embodiment of FIG. 4, the leads 208, 210, 214 may be formed pointing upward or downward as described above with regard to FIGS. 1 and 3.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. A method, comprising:
coupling a substrate interconnect to a substrate pad;
attaching at least two flip chips to said substrate interconnect to electrically connect together said chips; and
coupling at least one lead to each of the chips.

2. The method of claim 1, further comprising thermally coupling a heat slug to at least one of the chips.

3. The method of claim 2, further comprising thermally coupling the heat slug to a PC board.

4. The method of claim 1, further comprising forming an active circuit on the substrate interconnect.

5. The method of claim 1, wherein coupling the substrate interconnect comprises coupling the substrate interconnect to the substrate pad, said substrate interconnect formed of any of a group comprising silicon material, organic material and ceramic material.

6. The method of claim 1, further comprising forming a recessed area in the substrate pad to accommodate at least a portion of the substrate interconnect.

7. The method of claim 1, wherein attaching said chips to said substrate interconnect comprises:
forming copper pads on each chip; and
coupling the chips to the substrate interconnect using reflow of a lead free solder paste.

8. The method of claim 1, wherein attaching said chips to said substrate interconnect comprises forming solder balls on each chip.

9. The method of claim 1, wherein attaching said chips to said substrate interconnect comprises using plated solder.

10. An integrated circuit package, comprising:
at least two flip chips;
a plurality of leads, at least one lead coupled to at least one chip;
a substrate interconnect that electrically connects the at least two chips; and
a substrate pad coupled to the substrate interconnect.

11. The package of claim 10, wherein the substrate pad comprises a recessed area to contain a substrate interconnect.

12. The package of claim 10, further comprising a heat slug coupled to at least one chip.

13. The package of claim 12, wherein the heat slug is coupled to a PC board.

14. The package of claim 10, wherein the substrate interconnect comprises an active circuit.

15. The package of claim 10, wherein the substrate interconnect comprises any of a group comprising silicon material, organic material and ceramic material.

16. The package of claim 10, wherein the substrate interconnect electrically connects the two chips by way of copper pads formed on each chip and the reflow of a solder paste.

17. The package of claim 10, wherein the substrate interconnect electrically connects the two chips by way of any of a group comprising solder balls and plated solder.

18. The package of claim 10, further comprising wirebonds that electrically connect said at least two chips.

19. The package of claim 10, wherein at least one lead is oriented to point away from the substrate pad and toward the heat slug.

20. The package of claim 10, wherein at least one lead is oriented to point away from the heat slug and towards the substrate pad.

21. The package of claim 10, wherein the heat slug is encompassed within package epoxy.

22. The package of claim 10, wherein the heat slug protrudes through package epoxy.

23. An integrated circuit package, comprising:
a top surface of a substrate interconnect bonded to bottom surfaces of at least two flip chips, said substrate interconnect adapted to electrically connect the at least two chips;
a bottom surface of the substrate interconnect coupled to a substrate pad; and
a plurality of leads, at least one lead coupled to at least one chip.

24. The package of claim 23, further comprising a heat slug thermally bonded to a top surface of at least one of the chips.
